(19) United States
(12) Patent Application Publication
(10) Pub. No.: US 2026/0057126 A1
(43) Pub. Date: Feb. 26, 2026

(54) METHOD OF TESTING INFRASTRUCTURE MATERIALS ENCOMPASSING ALL SEASONAL CYCLES

(71) Applicants: The Texas A&M University System, College Station, TX (US); U.S. Army Engineer Research and Development Center, Vicksburg, MS (US)

(72) Inventors: Anand Jagadeesh Puppala, Southlake, TX (US); Nripojyoti Biswas, College Station, TX (US); Jeb Stuart Tingle, Vicksburg, MS (US)

(73) Assignees: The Texas A&M University System, College Station, TX (US); U.S. Army Engineer Research and Development Center, Vicksburg, MS (US)

(21) Appl. No.: 18/758,628

(22) Filed: Jun. 28, 2024

Related U.S. Application Data
(60) Provisional application No. 63/511,261, filed on Jun. 30, 2023.

(51) Int. Cl. G06F 30/17; G06F 30/20

(52) U.S. Cl. CPC G06F 30/17; G06F 30/20

(57) ABSTRACT

The invention provides a better simulation of environmental stressors in evaluating the structural stability and integrity of materials and infrastructure systems in all four seasons. In general, the selected procedures closely simulate different environmental conditions from all seasonal conditions on infrastructure materials for a target number of cycles. After subjecting the materials to the proposed process for a number of cycles, engineering tests can performed to address stability and cumulative distress. This procedure leads to a better screening of the materials, thereby leading to improved performance of infrastructure in the changing climatic conditions.

### CROSS REFERENCE TO RELATED APPLICATIONS

The present application claims priority to and benefit of U.S. Provisional Ser. No. 63/511,261 , filed Jun. 30, 2023, which is hereby incorporated by reference for all purposes as if set forth herein in its entirety.

### STATEMENT REGARDING FEDERALLY SPONSORED RESEARCH OR DEVELOPMENT

This invention was made with government support under Federal Award No. W912HZ23C0017 awarded by U.S. Army Engineer Research & Development Center. The government has certain rights in the invention.

### REFERENCE TO APPENDIX

Appendices are attached and incorporated herein by reference.

### BACKGROUND OF THE INVENTION

### Field of the Invention

The disclosure generally relates to a novel testing framework simulating annual seasonal changes comprising of all four seasons including winter freezing, spring thawing, summer drying and wetting conditions. More specifically, the disclosure relates to a novel testing framework simulating annual seasonal attributes including precipitation and temperature changes, linking microstructural aspects to macrostructural engineering properties of infrastructure materials, and linking the material properties changes with field performance parameters and attributes for use in construction activities.

### Description of the Related Art

Pavement and transportation infrastructures experience severe distress in the form of cracking in transverse and longitudinal directions and excessive permanent deformation or rutting due to seasonal environmental stressors, including cyclic temperature gradients and rainfall events.

### BRIEF SUMMARY OF THE INVENTION

The invention provides a better simulation of environmental stressors in evaluating the structural stability and integrity of materials and infrastructure systems in all four seasons. In general, the selected procedures closely simulate different environmental conditions from all seasonal conditions on infrastructure materials for a target number of cycles. After subjecting the materials to the proposed process for a number of cycles, engineering tests can be performed to address stability of materials and cumulative distresses. This procedure leads to a better screening of the materials, thereby leading to improved performance of infrastructure in the changing climatic conditions.

The novel testing protocol is of immense benefit to the infrastructure industry and state and federal agencies for an advanced screening of infrastructure materials subjected to all four seasonal environmental conditions. The use of this testing protocol helps to design transportation infrastructures with longer durability and serviceability. It also helps to reduce costs of rehabilitation and maintenance of civil infrastructures, which is billions of dollars annually.

### BRIEF DESCRIPTION OF THE SEVERAL VIEWS OF THE DRAWINGS

Aspects of the disclosure can be better understood with reference to the following drawings. The components in the drawings may be to scale, but emphasis is placed upon clearly illustrating the principles of the present disclosure. Moreover, in the drawings, like reference numerals designate corresponding parts throughout the several views, and in which:

FIG. 1 is a diagram of a system for testing and manufacturing infrastructure materials encompassing all seasonal cycles, in accordance with an example embodiment of the present disclosure;

FIG. 2 is a diagram of an algorithm for material property testing and manufacturing infrastructure materials encompassing all seasonal cycles, in accordance with an example embodiment of the present disclosure;

FIG. 3A-3B is a diagram of test results for comparative volume change material property testing of soil stabilization components, in accordance with an example embodiment of the present disclosure;

FIG. 4A-4C is a diagram of test results for comparative resilient modulus material property testing of soil stabilization components, in accordance with an example embodiment of the present disclosure; and FIG. 5A-5B is a diagram of test results for comparative moisture content material property testing of soil stabilization components, in accordance with an example embodiment of the present disclosure;

FIG. 6A-6B is a diagram of test results for comparative mass and volume change material property testing of soil stabilization components after F-T-W-D cycles, in accordance with an example embodiment of the present disclosure; and

FIG. 7A-7B is a diagram of test results for comparative mass and volume change material property testing of soil stabilization components after W-D-F-T cycles, in accordance with an example embodiment of the present disclosure.

### DETAILED DESCRIPTION

The Figures described above, and the written description of specific aspects and functions below are not presented to limit the scope of what Applicant has invented or the scope of the appended claims. Rather, the Figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present disclosure will require numerous implementation-specific decisions to achieve the developer's ultimate goal for the commercial embodiment. Such implementation-specific decisions may include, and likely are not limited to, compliance with system-related, business-related, government-related, and other constraints, which may vary by specific implementation or location, or with time. While a developer's efforts might be complex and time-consuming in an absolute sense, such efforts would be, nevertheless, a routine undertaking for those of ordinary skill in this art having benefit of this disclosure. It must be understood that the inventions disclosed and taught herein are susceptible to numerous and various modifications and alternative forms. The use of a singular term, such as, but not limited to, “a,” is not intended as limiting of the number of items. Further, the various methods and embodiments of the system can be included in combination with each other to produce variations of the disclosed methods and embodiments. Discussion of singular elements can include plural elements and vice-versa. References to at least one item may include one or more items. Also, various aspects of any embodiments could be used in conjunction with each other to accomplish the understood goals of the disclosure. Unless the context requires otherwise, the term “comprise” or variations such as “comprises” or “comprising,” should be understood to imply the inclusion of at least the stated element or step or group of elements or steps or equivalents thereof, and not the exclusion of a greater numerical quantity or any other element or step or group of elements or steps or equivalents thereof. The order of steps can occur in a variety of sequences unless otherwise specifically limited. The various steps described herein can be combined with other steps, interlineated with the stated steps, and/or split into multiple steps.

Traditional durability testing of infrastructure materials assesses the long-term serviceability either using wet-dry durability testing or freeze-thaw durability testing. However, a majority of the regions in the US (South, Southwest, and Midwest) experience cumulative distress from all four environmental stresses, and more regions are expected to face similar distresses due to changing climatic conditions. As a result, there is a need to include a novel testing protocol that addresses the effects of all environmental conditions by combining wetting, drying, freezing and thawing processes in evaluating the stability of infrastructure materials.

Current solutions only address partial seasonal simulation in assessing the durability of materials. Many times these methods do not provide comprehensive stability and material integrity assessments, and this often results in premature failures of civil infrastructure. Based on the literature and the past experience by researchers in durability studies, it is apparent that most agencies utilize separate processes to simulate the wetting and drying and freezing and thawing conditions for screening materials under various seasonal or environmental conditions. The infrastructure systems in most of the geographical regions, however, are exposed to all four processes, making it essential to develop durability steps that include all four processes. The severity of these processes and the environmental conditions vary from site to site. Each process and sequence can cause a certain amount of damage to stabilized materials that may accumulate with more cycles.

The methods of the invention include one or more of the below description. Variants of the methodology are contemplated. Based on the literature review and the inventors'past research experience in durability studies, it is apparent that most durable methods utilize separate processes to simulate the wetting and drying (W-D) and freezing and thawing (F-T) conditions for durability studies. The pavement systems in most geographical regions, however, are exposed to all four processes throughout the four seasons of a year, making it important to develop durability steps that include all four processes (W-D-F-T) in one or more combinations. Each process and sequence can cause certain amount of damage to stabilized materials that may accumulate with more cycles. To better understand the sequence of the processes and its effect on stabilized materials, at least two types of novel durability procedures can be followed. Method A can be a W-D-F-T cycle of the processes with wetting and drying as the first two processes followed by freezing and thawing processes. Method B can be an F-T-W-D cycle of the processes with freezing and thawing as the first two processes followed by wetting and drying processes. Variations of cycles with the four processes can include for example, W-F-T-D, W-D-W-F-T, and other variations.

Each of Method A and Method B can be performed in a number of cycles to simulate periodic environmental conditions that may be appropriate for geographical zones. For example and without limitations, the cycles can number five to fifty cycles with a starting value such as ten cycles, which are described in the following paragraph as an example.

For the Methods A and B (or variations), materials, such as soil samples including aggregates, can be collected and prepared, optionally including adding materials such as cement, lime, polymers, emulsifiers, co-additives along with traditional calcium-based stabilizers, silica-based compounds, recycled concrete aggregate fines (FRCA), crystalline-silica rich waste product, laboratory-grade nano-silica, organic or inorganic polymers, chemical accelerators or decelerators or other suitable materials or chemical stabilizers, and then subjected to one or more cycles with the processes for an appropriate period of time, generally from one day to one month. For example, if five days are chosen, then an example of a protocol could be the wetting process performed for 1.5 days, the drying process for 0.5 day, the freezing process for 2 days, and the thawing process for 1 day. Thus, approximately 5 days could be used to complete all four processes to establish a single cycle. The materials can be tested based on standard engineering material property testing protocols. For comparison, control or untreated soil specimens can be prepared and undergo the same cycles and processes and tested in a similar manner.

Based on this protocol tests have been performed to develop physical parameters that can impact soil stability through wet-dry and freeze-thaw cycles.

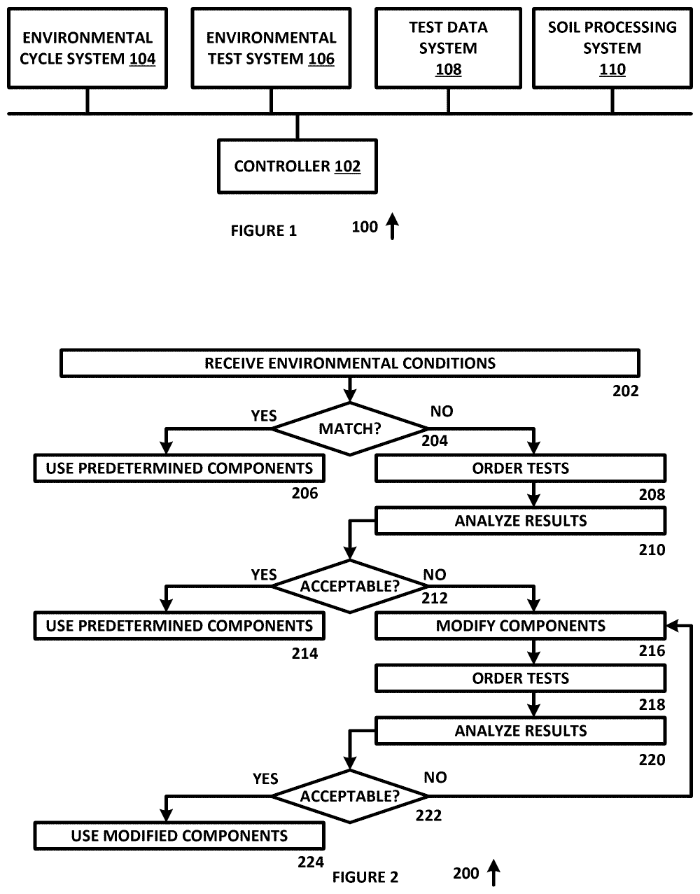

FIG. 1 is a diagram of a system for material property testing and manufacturing infrastructure materials encompassing all seasonal cycles, in accordance with an example embodiment of the present disclosure. System 100 includes environmental cycle system 104, environmental test system 106, test data system 108, material processing system 110 and controller 102, each of which can be implemented in hardware or a suitable combination of hardware and software.

Environmental cycle system 104 can be implemented as one or more algorithms that are stored in a working data memory device of a processor that cause the processor to transform environmental data into environmental cycle data. In one example embodiment, environmental cycle system 104 can receive location data and can retrieve historical weather data, to process the historical weather data to identify wet-dry and freeze thaw cycles. In one example embodiment, the wet-dry data and freeze thaw data can include additional data elements, such as a number of wet days followed by a number of dry days, a number of days freezing followed by a number of days thawing and so forth. In this example embodiment, the location data can include a soil type data, where the number of consecutive wet, dry, freeze and thaw days are used to analyze whether the soil type had time to go through a wet-dry cycle, a freeze-thaw cycle and so forth. A soil type such as clay that can retain water for longer periods of time can require a longer dry period to go through a wet-dry cycle or a freeze-thaw cycle than a soil type such as sand that does not retain water for very long. Environmental cycle system 104 can thus transform weather data and soil type data for a location into wet-dry cycle and freeze-thaw cycle data or other suitable environmental cycle data.

Environmental test system 106 can be implemented as one or more algorithms that are stored in a working data memory device of a processor that cause the processor to receive soil type data, wet-dry cycle data, freeze-thaw cycle data and other suitable environmental cycle data and to transform the data into environmental test data. In one example embodiment, a user can use controller 102 to request an environmental test program for a soil type in location if a library of available test data does not have a close enough match to that soil type in that location. For example, soil types can be identified that have characteristics that vary as a function of wet period length, dry period length, temperature and humidity differences between wet and dry periods, freeze period length, thaw period length, temperature and humidity differences between freeze and thaw periods or other suitable variables. Soil stabilizers such as cement, polymers, lime or other suitable materials can be added to the soil by various soil stabilization treatment methods, such as by a road mix method, central mix method, full depth recycling method, base treatment, sub-base treatment and other suitable treatment methods. A user can review a library of data and can determine that the soil stabilizer treatments for the closest soil types are too different to base a decision on. For example, a soil type in one location could be 80% clay, 15% silt and 5% stone, and in a second location could be 60% clay, 25% sand, 10% silt and 5% chalk. The first location could have 8 freeze-thaw cycles and 10 wet-dry cycles, and the second location could have 2 freeze-thaw cycles and 14 wet-dry cycles. The optimal soil treatment for the first location could be 8% cement and the optimal soil treatment for the second location could be 10% cement and 10% FRCA. For a testing location with a soil type of 70% clay, 15% sand and 15% chalk, and with 3 freeze-thaw cycles and 4 wet-dry cycles, this closest data would be insufficient to determine the optimal soil treatment. Environmental test system 106 allows a user to evaluate such variables and to design test programs for generating new data as needed to optimize soil or material processing.

Test data system 108 can be implemented as one or more algorithms that are stored in a working data memory device of a processor that cause the processor to receive and process test data for use with environmental test system 106. In one example embodiment, test data system 108 can include machine learning algorithms that can process a large number of data sets to identify patterns in the data that can be used to select soil treatments, to order soil tests and for other suitable purposes.

Material processing system 110 can be implemented as one or more algorithms that are stored in a working data memory device of a processor that cause the processor to control soil processing equipment. In one example embodiment, material processing system 110 can process soil in accordance with a treatment process, such as by a road mix method, central mix method, full depth recycling method, base treatment, sub-base treatment and other suitable treatment methods. The soil processing can use one or more additives such as cement, lime, certain co-additives or other suitable additives. Material processing system 110 can thus transform soil from a native form into a processed form to provide improved soil stability for roadways, buildings and other structures that are built on the soil.

Controller 102 can be implemented as one or more algorithms that are stored in a working data memory device of a processor that cause the processor to interface with environmental cycle system 104, environmental test system 106, test data system 108 and material processing system 110 to optimize soil treatment for the soil type, freeze-thaw cycles, wet-dry cycles and other environmental conditions at a location. Controller 102 can generate user interface controls and data displays as discussed herein to allow a user to either select a stored soil conditioning treatment or to order additional tests to optimize the soil conditioning treatment.

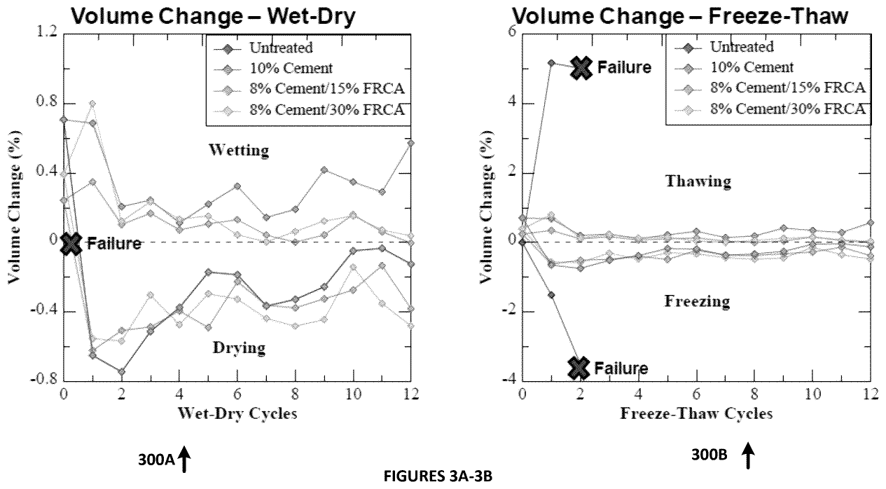

FIG. 2 is a diagram of an algorithm for material property testing and manufacturing infrastructure materials encompassing all seasonal cycles, in accordance with an example embodiment of the present disclosure. Algorithm 200 can be implemented in hardware or a suitable combination of hardware and software.

Algorithm 200 begins at 202, where environmental conditions are received. In one example embodiment, the environmental conditions can include soil type, wet-dry cycle data, freeze-thaw cycle data and other suitable environmental condition data as discussed and described herein. The algorithm then proceeds to 204.

At 204, it is determined whether there is a match between the environmental conditions and stored soil treatment data. In one example embodiment, prior sets of environmental data indexed to soil treatment processes that have been used previously can be used to evaluate whether the current set of environmental conditions matches any of the prior sets. Machine learning or other suitable data processing can be used to extrapolate between a current set of environmental data and prior sets, such as to identify soil treatment processes, to identify that additional material property testing is needed or to identify other suitable data. If it is determined that a match has been obtained, the algorithm proceeds to 206 where predetermined soil conditioning components are used, such as a soil processing method, soil stabilizers and other suitable components. Otherwise, the algorithm proceeds to 208.

At 208, one or more tests are ordered. In one example embodiment, the tests can include a number of wet-dry cycles, a number of freeze-thaw cycles, moisture and temperature parameters for the wet-dry cycles and freeze-thaw cycles, soil treatment processes and additives and other suitable data. Suitable sequences of tests can be performed to simulate typical environmental conditions for a location. For example, a location could experience a large number of wet-dry cycles with a small number of freeze-thaw cycles, a large number of freeze-thaw cycles with a small number of wet-dry cycles, wet-dry cycles during freeze or thaw periods, freeze-thaw cycles during wet or dry periods and so forth. Likewise, complex cycles such as a freeze period followed by snow, then a series of thaw and freeze periods with high moisture as the snow melts, followed by a long dry period could be typical for a location. The testing cycles can be configured to simulate the actual environmental conditions at the location as a function of historical data. The algorithm then proceeds to 210.

At 210, soil treatment test results are analyzed. In one example embodiments, the unconfined compressive strength, maximum dry density, volume change, material loss, stiffness or resilient modulus, moisture content and other suitable parameters can be measured and analyzed. The algorithm then proceeds to 212.

At 212, it is determined whether the results were acceptable for an intended purpose. In one example embodiment, the purpose can be selected from predetermined classes, such as roadway, building base or other suitable classes. If it is determined that the results are acceptable, the algorithm proceeds to 214 where the predetermined components are used, otherwise the algorithm proceeds to 216.

At 216, one or more components are modified. In one example embodiment, the components can include cement content percentage, polymer content percentage, lime content percentage or co-additive such as FRCA content percentage or other suitable soil stability additive content modifications. In another example embodiment, the components can include wet-dry cycle parameters such as length of time of “wet” and “dry” periods, freeze-thaw cycle parameters such as length of time of “freeze” and “thaw” periods, or other suitable parameters. The algorithm then proceeds to 218.

At 218, tests with the modified components are ordered. In one example embodiment, the test order can be automatically populated with the component modifications, the source for soil samples and additives or other suitable data. Automated test equipment (ATE) can also be used to process each sample to ensure uniform handling, such as for mixing of soil stability additives, wet-dry and freeze-thaw cycles and other suitable processes. The algorithm then proceeds to 220.

At 220, the results of the tests are analyzed. In one example embodiment, a substantial period of time can elapse, such as where the number of freeze-thaw and wet-dry cycles is substantial, the length of time for each freeze, thaw, wet or dry period is substantial or if other causes exist for a lengthy period of elapsed time associated with the material property testing. In such circumstances, notification data can be generated to alert an operator of an approaching end of a test period, so that accommodations can be made for the next stage of the material property testing. If ATE is used, scheduling of ATE processes can be coordinated, such as to delay a start of a first process to ensure availability of equipment for the second process and so forth. The algorithm then proceeds to 222.

At 222, it is determined whether the results are acceptable. In one example embodiment, the parameters for a successful result can be determined in advance, such as where a limit for an acceptable volume change, resilient modulus or other suitable parameters or metrics can be established. In another example embodiment, one of a plurality of samples with the best performance can be selected, or other suitable selection criteria can also or alternatively be implemented. If it is determined that the results are acceptable, then the algorithm proceeds to 224 where the modified components are used for construction purposes. Otherwise, the algorithm returns to 216 where new parameters are tested.

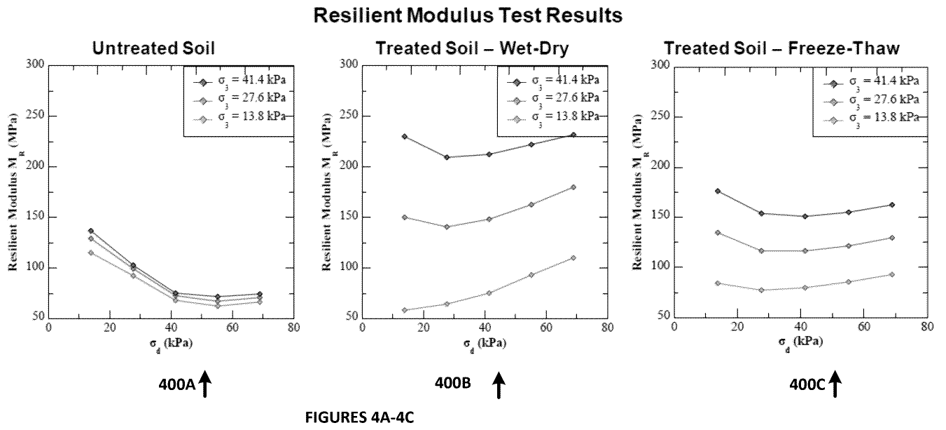

FIGS. 3A-3B are diagrams of test results 300A and 300B for comparative volume change material property testing of soil stabilization components, in accordance with an example embodiment of the present disclosure. Test results 300A and 300B include volume change parameter measurements for wet-dry and freeze-thaw testing for 1) an untreated soil sample, 2) a soil sample with 10% cement added, 3) a soil sample with 8% cement and 15% FRCA added and 4) a soil sample with 8% cement and 15% FRCA added. The untreated soil samples encountered failures (collapse) after 1 cycle for wet-dry testing and after 2 cycles for freeze-thaw testing, but all other samples exhibited acceptable behavior after 12 cycles. Depending on construction parameters, all three soil treatments could be acceptable, or if a maximum acceptable volume change metric was known (such as 0.4 % volume change after 12 cycles), then one or more of the soil treatments could be excluded.

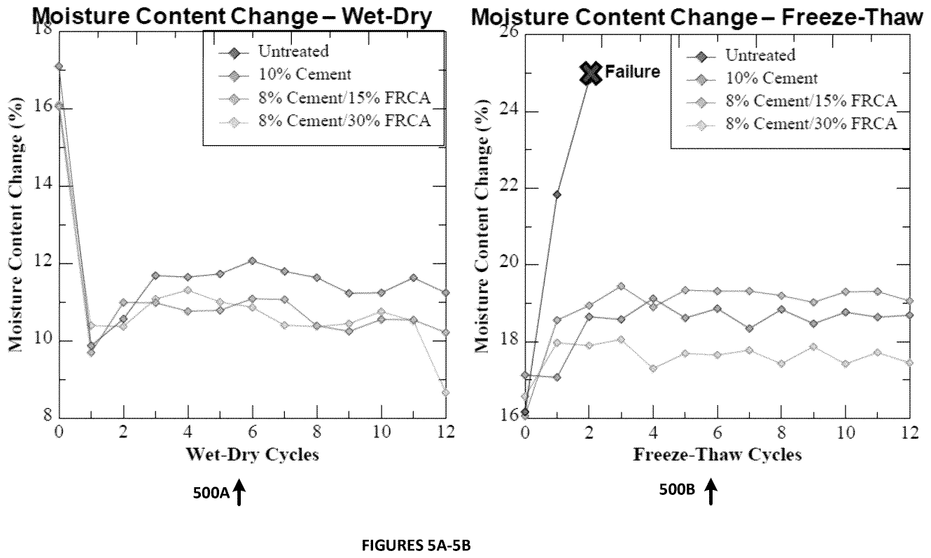

FIGS. 4A-4C are diagrams of test results 400A-400C for comparative resilient modulus testing of soil stabilization components, in accordance with an example embodiment of the present disclosure. Test results 400A-400C include resilient modulus parameter measurements for wet-dry and freeze-thaw testing for 1) an untreated soil sample, 2) a soil sample with 10% cement added, 3) a soil sample with 8% cement and 15% FRCA added and 4) a soil sample with 8% cement and 15% FRCA added. The untreated soil samples exhibits softening behavior, whereas the treated soil samples exhibited hardening behavior even after durability testing. Specimens subjected to wet-dry cycles exhibited higher stiffness than those subjected to freeze-thaw cycles. Depending on construction parameters, all three soil treatments could be acceptable, or if a maximum acceptable resilient modulus metric was known, then one or more of the soil treatments could be excluded.

FIGS. 5A-5B are diagrams of test results 500A and 500B for comparative moisture content material property testing of soil stabilization components, in accordance with an example embodiment of the present disclosure. Test results 500A and 500B include moisture content change parameter measurements for wet-dry and freeze-thaw testing for 1) an untreated soil sample, 2) a soil sample with 10% cement added, 3) a soil sample with 8% cement and 15% FRCA added and 4) a soil sample with 8% cement and 15% FRCA added. The untreated soil samples encountered failures (collapse) after 3 cycles for freeze-thaw testing, but all other samples exhibited acceptable behavior after 12 cycles. Depending on construction parameters, all three soil treatments could be acceptable, or if a maximum acceptable moisture content metric was known, then one or more of the soil treatments could be excluded.

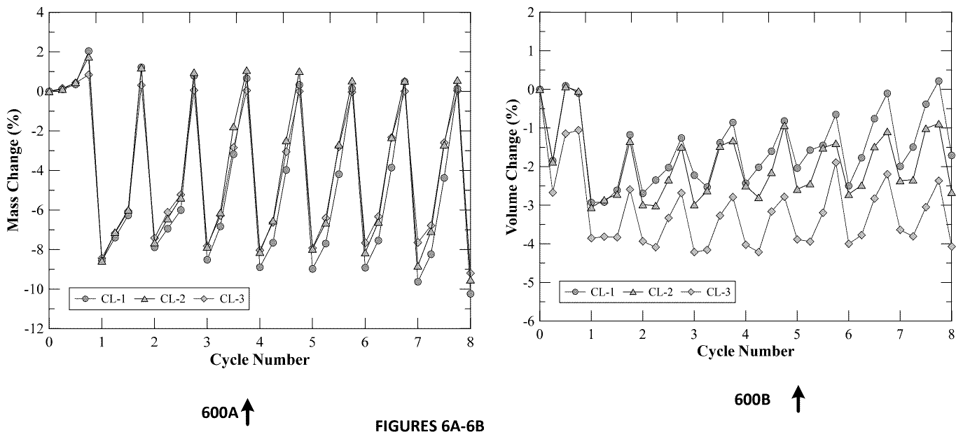

FIGS. 6A-6B are diagrams of test results 600A and 600B for comparative mass and volume change material property testing of soil stabilization components after F-T-W-D cycles, in accordance with an example embodiment of the present disclosure. Test results 600 include mass and volume change measurements for samples formed from CL 9% Portland Type 1 Cement with F-T-W-D testing performed for 8 cycles.

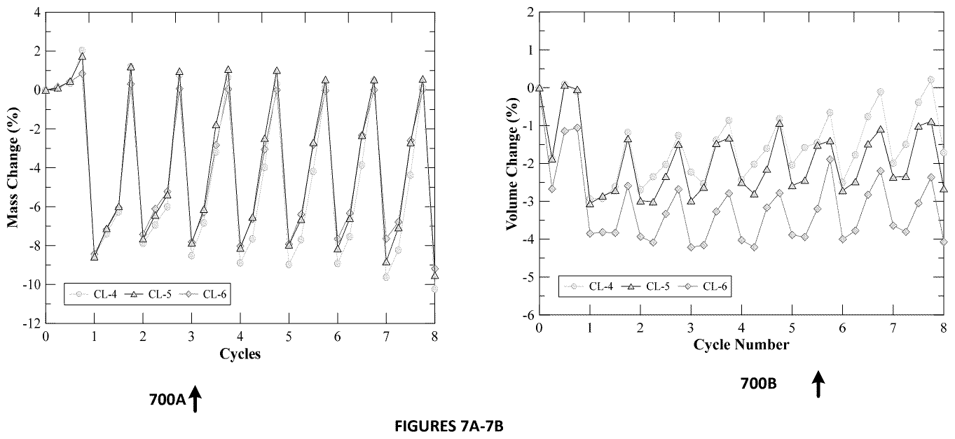

FIGS. 7A-7B are diagrams of test results 700A and 700B for comparative mass and volume change material property testing of soil stabilization components after W-D-F-T cycles, in accordance with an example embodiment of the present disclosure. Test results 700 include mass and volume change measurements for samples formed from CL 9% Portland Type 1 Cement, with W-D-F-T testing performed for 8 cycles.

Other and further embodiments utilizing one or more aspects of the inventions described above can be devised without departing from the disclosed invention as defined in the claims. Various numbers of cycles, length of cycles, combinations of processes in each cycle, and other variations than those specifically disclosed herein within the scope of the claims.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y. ” As used herein, phrases such as “from about X to Y” mean “from about X to about Y. ”

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications, on one or more processors (where a processor includes one or more microcomputers or other suitable data processing units, memory devices, input-output devices, displays, data input devices such as a keyboard or a mouse, peripherals such as printers and speakers, associated drivers, control cards, power sources, network devices, docking station devices, or other suitable devices operating under control of software systems in conjunction with the processor or other devices), or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections. The term “data” can refer to a suitable structure for using, conveying or storing data, such as a data field, a data buffer, a data message having the data value and sender/receiver address data, a control message having the data value and one or more operators that cause the receiving system or component to perform a function using the data, or other suitable hardware or software components for the electronic processing of data.

In general, a software system is a system that operates on a processor to perform predetermined functions in response to predetermined data fields. A software system is typically created as an algorithmic source code by a human programmer, and the source code algorithm is then compiled into a machine language algorithm with the source code algorithm functions, and linked to the specific input/output devices, dynamic link libraries and other specific hardware and software components of a processor, which converts the processor from a general purpose processor into a specific purpose processor. This well-known process for implementing an algorithm using a processor should require no explanation for one of even rudimentary skill in the art. For example, a system can be defined by the function it performs and the data fields that it performs the function on. As used herein, a NAME system, where NAME is typically the name of the general function that is performed by the system, refers to a software system that is configured to operate on a processor and to perform the disclosed function on the disclosed data fields. A system can receive one or more data inputs, such as data fields, user-entered data, control data in response to a user prompt or other suitable data, and can determine an action to take based on an algorithm, such as to proceed to a next algorithmic step if data is received, to repeat a prompt if data is not received, to perform a mathematical operation on two data fields, to sort or display data fields or to perform other suitable well-known algorithmic functions. Unless a specific algorithm is disclosed, then any suitable algorithm that would be known to one of skill in the art for performing the function using the associated data fields is contemplated as falling within the scope of the disclosure. For example, a message system that generates a message that includes a sender address field, a recipient address field and a message field would encompass software operating on a processor that can obtain the sender address field, recipient address field and message field from a suitable system or device of the processor, such as a buffer device or buffer system, can assemble the sender address field, recipient address field and message field into a suitable electronic message format (such as an electronic mail message, a TCP/IP message or any other suitable message format that has a sender address field, a recipient address field and message field), and can transmit the electronic message using electronic messaging systems and devices of the processor over a communications medium, such as a network. One of ordinary skill in the art would be able to provide the specific coding for a specific application based on the foregoing disclosure, which is intended to set forth exemplary embodiments of the present disclosure, and not to provide a tutorial for someone having less than ordinary skill in the art, such as someone who is unfamiliar with programming or processors in a suitable programming language. A specific algorithm for performing a function can be provided in a flow chart form or in other suitable formats, where the data fields and associated functions can be set forth in an exemplary order of operations, where the order can be rearranged as suitable and is not intended to be limiting unless explicitly stated to be limiting.

The invention has been described in the context of preferred and other embodiments and not every embodiment of the invention has been described. Obvious modifications and alterations to the described embodiments are available to those of ordinary skill in the art. The disclosed and undisclosed embodiments are not intended to limit or restrict the scope or applicability of the invention conceived of by the Applicant, but rather, in conformity with the patent laws, Applicant intend to protect fully all such modifications and improvements that come within the scope of the following claims.

What is claimed is:

1. A method of testing infrastructure materials encompassing all seasonal cycles, comprising:
obtaining an infrastructure material to be tested;
processing the material through at least one cycle comprising wetting, drying, freezing, and thawing, and
testing a material performance under engineering tests.

2. The method of claim 1, wherein the cycle comprises in order wetting, drying, freezing, and thawing.

3. The method of claim 1, wherein the cycle comprises in order freezing, thawing. wetting, and drying.

4. The method of claim 1, comprising applying chemical stabilizers to the material prior to processing the materials.

5. The method of claim 1, further comprising:
mixing a first soil stability component in a first sample;
mixing a second soil stability component in a second sample; and
processing the first sample and the second sample through the at least one cycle comprising wetting, drying, freezing, and thawing.

6. The method of claim 5 further comprising testing the material performance under engineering tests for the first sample and the second sample.

7. The method of claim 6 further comprising:
selecting one of the first soil stability component and the second soil stability component for use at a construction site; and
processing infrastructure material at the construction site using the selected one of the first soil stability component and the second soil stability component.

8. A method of testing infrastructure materials encompassing all seasonal cycles, comprising:
obtaining an infrastructure material to be tested from a location;
determining one or more material properties of the infrastructure material;
determining environmental conditions for the location;
determining whether testing has been performed for an equivalent infrastructure material with the material properties for the environmental conditions;
using a soil stability component associated with the infrastructure material if testing has been performed for an equivalent infrastructure material with the same material properties for the same environmental conditions; and
testing the infrastructure material if testing has not been performed for an equivalent infrastructure material with the same material properties for the same environmental conditions.

9. The method of claim 8 wherein testing the infrastructure material comprises processing the material through at least one cycle comprising wetting, drying, freezing, and thawing.

10. The method of claim 9, wherein the cycle comprises in order wetting, drying, freezing, and thawing.

11. The method of claim 9, wherein the cycle comprises in order freezing, thawing. wetting, and drying.

12. The method of claim 9, comprising applying chemical stabilizers to the material prior to processing the materials.

13. The method of claim 9, further comprising:
mixing a first soil stability component in a first sample;
mixing a second soil stability component in a second sample; and
processing the first sample and the second sample through the at least one cycle comprising wetting, drying, freezing, and thawing.

14. The method of claim 13 further comprising testing the material performance under engineering tests for the first sample and the second sample.

15. The method of claim 14 further comprising:
selecting one of the first soil stability component and the second soil stability component for use at a construction site; and
processing infrastructure material at the construction site using the selected one of the first soil stability component and the second soil stability component.

16. A system for selecting a soil stability component for processing soil, comprising:
an environmental cycle system operating on a processor that is configured to receive environmental data for a location and soil type data for the location and to process the environmental data to generate a plurality of cycles selected from the group comprising wet, dry, freeze and thaw;
an environmental test system operating on the processor that is configured to receive the plurality of cycles and to determine whether testing has been performed for equivalent cycles to the plurality of cycles for an equivalent material for the soil type data; and
a material processing system operating on the processor that is configured to select a soil stability component for processing soil at the location if it is determined that testing has been performed for equivalent cycles to the plurality of cycles for an equivalent material for the soil type data, and to order testing if it is determined that testing has not been performed for equivalent cycles to the plurality of cycles for an equivalent material for the soil type data.

17. The system of claim 16 further comprising a test data system that is configured to receive the plurality of cycles and to generate a test process to simulate the plurality of cycles for a plurality of samples of soil, each mixed with a soil stability component.
